(19) United States
(12) Patent Application Publication
(10) Pub. No.: US 2020/0312740 A1
(43) Pub. Date: Oct. 1, 2020

(54) LOW THERMAL RESISTANCE POWER MODULE PACKAGING

(71) Applicant: CORNING INCORPORATED, CORNING, NY (US)

(72) Inventors: Abhijit Rao, Painted Post, NY (US); Nagaraja Shashidhar, Painted Post, NY (US)

(21) Appl. No.: 16/826,641

(22) Filed: Mar. 23, 2020

Related U.S. Application Data
(60) Provisional application No. 62/825,204, filed on Mar. 28, 2019.

(51) Int. Cl. H01L 23/373; H01L 21/48

(52) U.S. Cl. CPC H01L 23/3735; H01L 21/4882

(57) ABSTRACT

Embodiments of the disclosure relate to a method of preparing a direct plated substrate. In the method, a dielectric layer is provided that has a first major surface, a second major surface opposite to the first major surface, and a thickness between the first major surface and the second major surface. The thickness of the dielectric layer is no more than 100 μm. A first metal layer is applied to the first major surface of the dielectric layer. A second metal layer is applied to the second major surface of the dielectric layer. A base plate is joined to the second metal layer, and a metal substrate is joined to the first metal layer. A direct plated substrate made according to the method is also described herein.

### CROSS-REFERENCE TO RELATED APPLICATIONS

This application claims the benefit of priority under 35 U.S.C. § 119 of U.S. Provisional Application Ser. No. 62/825,204 filed on Mar. 28, 2019 the contents of which are relied upon and incorporated herein by reference in their entirety as if fully set forth below.

### BACKGROUND

The disclosure relates generally to substrates for power module packaging and, in particular, to a power module substrate having a thin dielectric substrate and methods for making same. There continues to be a growing demand for power semiconductor or integrated circuit (IC) modules and other electric elements with higher power density, higher reliability, and improved cost effectiveness. Miniature power and electric modules are used extensively in a range of applications including automobiles, hard drives, data storage devices, and many other electronic products.

### SUMMARY

In one aspect, embodiments of the disclosure relate to a method of preparing a direct plated substrate. In the method, a dielectric layer is provided that has a first major surface, a second major surface opposite to the first major surface, and a thickness between the first major surface and the second major surface. The thickness of the dielectric layer is no more than 100 μm. A first metal layer is applied to the first major surface of the dielectric layer. A second metal layer is applied to the second major surface of the dielectric layer. A base plate is joined to the second metal layer, and a metal substrate is joined to the first metal layer.

In another aspect, embodiments of the disclosure relate to a direct plated substrate. The direct plated substrate includes a dielectric layer, a first metal layer, and a second metal layer. The dielectric layer has a first major surface, a second major surface opposite to the first major surface, and a thickness between the first major surface and the second major surface. The thickness is no more than 100 μm. The first metal layer is applied to the first major surface and has a thickness of from 2 μm to 50 μm. The second metal layer is applied to the second major surface and has a thickness of from 2 μm to 50 μm. A metal substrate is joined to the first metal layer, and a base plate is joined to the second metal layer.

In a further aspect, embodiments of the disclosure relate to an electronic packaging. The electronic packaging includes a dielectric layer, a first metal layer, and a second metal layer. The dielectric layer has a first major surface, a second major surface opposite to the first major surface, and a thickness between the first major surface and the second major surface. The thickness is no more than 100 μm. The first metal layer is applied to the first major surface, and the second metal layer is applied to the second major surface. A metal substrate has a first substrate surface and a second substrate surface in which the second substrate surface is joined to the first metal layer. A base plate is joined to the second metal layer, and a semiconductor component is joined to the first substrate surface of the metal substrate.

In still another aspect, embodiments of the disclosure relate to a method in which a direct plated substrate is provided. The directed plated substrate includes a dielectric layer having a first major surface, a second major surface opposite to the first major surface, and a thickness between the first major surface and the second major surface. The thickness is no more than 100 μm. The dielectric layer has a first metal layer applied to the first major surface and a second metal layer applied to the second major surface. Further, in the method, the direct plated substrate is diced into a plurality of segments. The plurality of segments is positioned onto a base plate to create regions of electrical isolation. The base plate is joined to second metal layer, and a metal substrate is joined to the first metal layer.

In yet another aspect, embodiments of the disclosure relate to a lead frame packaging. The lead frame packaging includes a direct plated substrate. The direct plated substrate includes a dielectric layer comprising a first major surface, a second major surface opposite to the first major surface, and a thickness between the first major surface and the second major surface. The thickness is no more than 100 μm. A first metal layer is applied on the first major surface, and a second metal layer is applied on the second major surface. The lead frame packaging also includes a metal substrate having a first substrate surface and a second substrate surface. The second substrate surface is joined to the first metal layer. Further, the electronic packaging includes a base plate joined to the second metal layer, a semiconductor component joined to the first substrate surface of the metal substrate of the direct plated substrate, and at least one lead configured to provide electrical communication with the semiconductor component.

Additional features and advantages will be set forth in the detailed description that follows, and, in part, will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

### BRIEF DESCRIPTION OF THE DRAWINGS

The accompanying drawings are included to provide a further understanding and are incorporated in and constitute a part of this specification. The drawings illustrate one or more embodiment(s), and together with the description serve to explain principles and the operation of the various embodiments. In the drawings:

FIG. 1 depicts a directed plated substrate having a ribbon ceramic dielectric layer, according to an exemplary embodiment.

FIG. 2 depicts a stage of the assembly of a direct plated substrate, according to an exemplary embodiment.

FIG. 3 depicts another stage of the assembly of a direct plated substrate, according to an exemplary embodiment.

FIG. 4 depicts still another stage of the assembly of direct plated substrate, according to an exemplary embodiment.

FIG. 5 depicts another embodiment of a direct plated substrate having a discontinuous dielectric layer, according to an exemplary embodiment.

FIG. 6 depicts another embodiment of a direct plated substrate having a metal substrate with varying thickness, according to an exemplary embodiment.

FIG. 7 depicts an embodiment of a lead frame incorporating a direct plated substrate, according to an exemplary embodiment.

FIG. 8 is a graph of the junction temperature of various electronic packagings according to conventional design and according to the present disclosure.

FIG. 9 is a graph of the power output of various electronic packagings according to conventional design and according to the present disclosure.

### DETAILED DESCRIPTION

Embodiments of the present disclosure relate to a method of preparing a direct plated substrate for power electronic packaging having lower thermal resistance than conventional designs. The method of preparing the direct plated substrates allows for the use of a thinner dielectric layer and the ability to join the dielectric layer to metal base plate with less intervening material. These two factors contribute to an overall smaller package with lower thermal resistance. By providing a substrate with lower thermal resistance, power modules mounted to the substrate are able to operate at lower temperatures and maintain higher outputs than would otherwise be possible for a given temperature condition. Conventional direct bonded copper (DBC) designs utilize high temperature and pressure to bond copper foils to each side of the dielectric layer. The high temperature and pressure requires the use of thicker components (>150 μm thick foils and >250 μm thick dielectric layer) to withstand the processing conditions. In contrast, the direct plated substrates according to the present disclosure are manufactured in a manner that allows for the utilization of ceramic ribbon having thickness of less than 100 μm as a dielectric layer. Metal layers are plated on the surfaces of the dielectric layer, and metal substrates and base plates are bonded to these layers instead of directly to the dielectric layer at lower temperatures and pressures, resulting in an overall thinner package and lower thermal resistance. Also, advantageously, less expensive materials are able to be utilized for the dielectric layer despite having thermal properties potentially inferior to more expensive dielectric materials without sacrificing performance. A variety of embodiments of the direct plated substrate and method of producing same are provided herein. These embodiments are presented by way of example only and not by way of limitation.

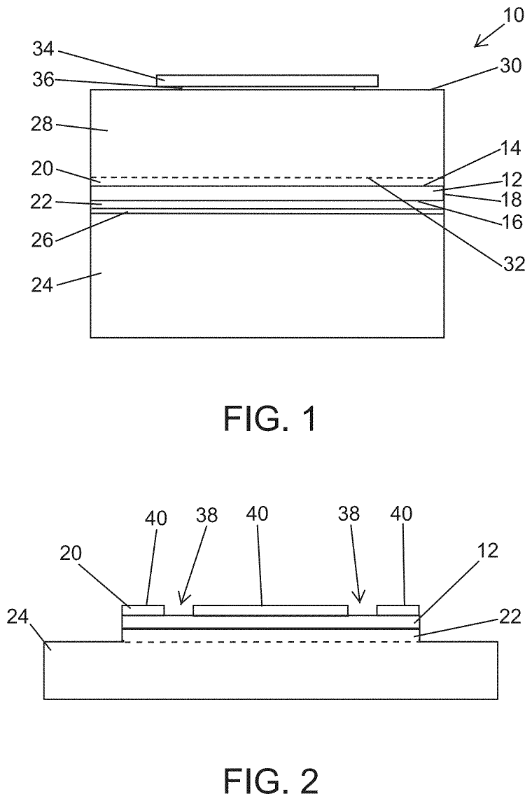

FIG. 1 depicts an embodiment of a substrate 10 according to the present disclosure. The substrate 10 includes a dielectric layer 12 having a first major surface 14 and a second major surface 16. The first major surface 14 is connected to the second major surface 16 by a minor surface 18 that extends around the perimeter of the substrate 10. Disposed on the first major surface 16 is a first metal layer 20, and disposed on the second major surface 16 is a second metal layer 22. In embodiments, the first metal layer 20 is plated to the first major surface 14, and the second metal layer 20 is plated to the second major surface 16. In embodiments, plating is carried out, for example, using electroplating or electroless plating. In other embodiments, the first metal layer 20 is applied using another technique such as direct bonding or screen printing.

In embodiments, the dielectric layer 12 may be any of a variety of dielectric materials. For example, in embodiments, the dielectric layer 12 comprises at least one of alumina (Al₂O₃), aluminum nitride (AlN), beryllium oxide (BeO), or zirconia toughened alumina (ZTA). In embodiments, the dielectric layer 12 is formed or cut from a ribbon ceramic.

Further, in embodiments, the dielectric layer 12 has an average thickness between the first major surface 14 and the second major surface 16 of 100 μm or less. In other embodiments, the dielectric layer 12 has an average thickness of 80 μm of less. In still other embodiments, the dielectric layer 12 has an average thickness of 40 μm of less. In embodiments, the dielectric layer 12 has an average thickness of at least 5 μm, at least 10 μm, or at least 20 μm. While the dielectric layer 12 is particularly thin, e.g., less than 100 μm in many preferred embodiments, such as due to increase flexibility and low consumption of space; in contemplated embodiments, the dielectric layer 12 may be thicker, such as up to 200 μm, such as up to 300 μm, or thicker.

In embodiments, the first metal layer 20 and the second metal layer 22 comprise at least one of copper, aluminum, silver, nickel, gold, or tin, among others. In embodiments, the first metal layer 20 comprises the same metal as the second metal layer 22. In other embodiments, the first metal layer 20 comprises a metal different from the second metal layer 22.

In embodiments, the first metal layer 20 and the second metal layer 22 have an average thickness of from 2 μm to 50 μm. In other embodiments, the first metal layer 20 and the second metal layer 22 have an average thickness of from 10 μm to 30 μm. In still other embodiments, the first metal layer 20 and the second metal layer 22 have an average thickness of from 20 μm to 25 μm. In embodiments, the first metal layer 20 has the same thickness as the second metal layer 22. In other embodiments, the first metal layer 20 has a thickness different from the thickness of the second metal layer 22.

As shown in FIG. 1, the second metal layer 22 is connected to a base plate 24 via joint interface 26. In embodiments, the joint interface 26 is a solder layer. In embodiments, the solder layer comprises, e.g., silver-tin solder or silver-gold-copper (SAC) solder, among others. In other embodiments, the joint interface 26 is a sintered material, such as sintered silver. In embodiments, the joint interface 26 has a thickness of from 1 μm to 25 μm.

The base plate 24 provides a heat sink to transfer heat away from the dielectric layer 12. In embodiments, the base plate 24 may be mounted to cooling fins, heat exchangers, fans, etc. to dissipate heat. In exemplary embodiments, the base plate 24 is at least one of copper or aluminum. In embodiments, the base plate 24 has a thickness of from 0.5 mm to 10 mm.

The first metal layer 20 is connected to a metal substrate 28. The metal substrate 28 has a first substrate surface 30 and a second substrate surface 32 that is on the side of the metal substrate 28 opposite to the first substrate surface 30. In embodiments, the thickness of the metal substrate 28 between the first substrate surface 30 and the second substrate surface 32 is from 100 μm to 1 mm. For IC power modules designed to carry high current, the thickness of the metal substrate 28 can be increased to a desired level to decrease Joule heating (i.e., resistive heating due to the resistance of metal substrate 28 material). Advantageously, such a modification can be made without redesigning the entire power module packaging.

In embodiments, the metal substrate 28 is made of the same material as the first meal layer 20. However, the metal substrate 28 may be made of a material that is different from the first metal layer 20. In general, the metal substrate 28 will be made of a material selected from one of the materials listed above for the metal layers 20, 22.

In embodiments, the first metal layer 20 and the metal substrate 28 are connected via ultrasonic bonding. In particular, the second substrate surface 32 is placed in contact with the first metal layer 20, and ultrasonic acoustic vibrations and pressure are applied to the metal substrate 28 and first metal layer 20 to create a solid-state joint between the first metal layer 20 and the metal substrate 28. That is, upon ultrasonic bonding, the first metal layer 22 and the metal substrate 28 become a unitary layer of metal, having a thickness of about 102 μm to about 1050 μm, that is joined to the dielectric layer 12. Thus, the second substrate surface 32 essentially is eliminated after ultrasonic bonding, which is denoted in FIG. 1 with the use of a dashed line representing the boundary between the metal substrate 28 and the first metal layer 20 prior to ultrasonic bonding. In other embodiments, thermal compression bonding can be used to bond copper-copper surfaces of the metal substrate 28 and the first metal layer 20.

A semiconductor component 34 is joined to the first substrate surface 30. In embodiments, the semiconductor component 34 is an integrated circuit (IC) power module, such as an insulated-gate bipolar transistor (IGBT) or a power metal-oxide-semiconductor field-effect transistor (MOSFET), among others. In embodiments, the semiconductor component 34 is joined to the first substrate surface 30 of the metal substrate 28 via a joint layer 36, which, in embodiments, is a solder layer or sintered silver.

FIG. 1 provides a general structure of a direct plated substrate 10 according to the present disclosure. However, in order to incorporate the direct plated substrate 10 into an electronic packaging, various modifications may be made during assembly of the direct plated substrate 10. FIGS. 2-4 depict such modifications made during assembly. Starting with FIG. 2, the dielectric layer 12 has been plated with the first metal layer 20 and the second metal layer 22, and the second metal layer 22 has been joined to the base plate 24. In the embodiment depicted in FIG. 2, the second metal layer 22 was joined to the base plate 24 with ultrasonic bonding, as denoted by the dashed line between second metal layer 22 and the base plate 24.

As can be seen in FIG. 2, the first metal layer 20 has been provided with a pattern of electrical connections with gaps 38 provided between paths 40 to electrically isolate the paths 40. In an embodiment, the first metal layer 20 may be applied in a manner that creates a desired pattern, or a uniform layer may be first applied followed by selective removal of material to create the gaps 38 and define the paths 40. In one exemplary embodiment, material may be selectively removed by etching the first metal layer 20.

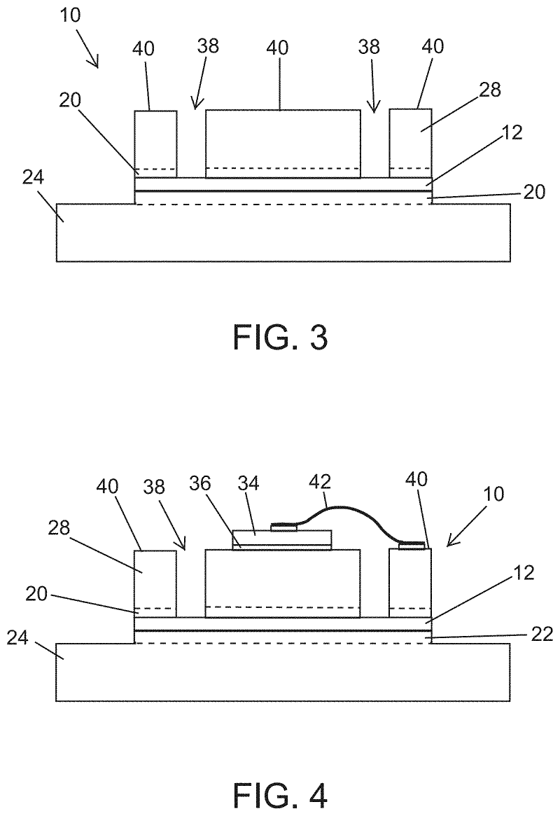

With reference now to FIG. 3, the metal substrate 28 has been joined to the first metal layer 20. The metal substrate 28 was joined by ultrasonic bonding, which is denoted by the dashed line between the first metal layer 20 and the metal substrate 28. As shown in FIG. 3, the metal substrate 28 was also provided with a pattern of electrical connections that matches the pattern of electrical connections of the first metal layer 20. As with the pattern in the first metal layer 20, the pattern in the metal substrate 28 may be formed by selective removal of material (e.g., etching). For example, the metal substrate 28 can be carried on a polymer carrier, etched on the carrier, and then the carrier may be used to place the metal substrate 28 over the first metal layer 20. Upon placement of the metal substrate 28 on the first metal layer 20, the polymer carrier may then be removed, followed by permanent joining leaving the construction shown in FIG. 3.

As shown in FIG. 4, the semiconductor component 34 is soldered or silver sintered to one path 40 of the metal substrate 28. A wire 42 connects the semiconductor component 34 to another path 40 of the metal substrate 28. In the embodiment depicted in FIG. 4, the wire 42 is soldered or silver sintered to the semiconductor component 34 at one end and to a path 40 on the metal substrate 28 at the other end.

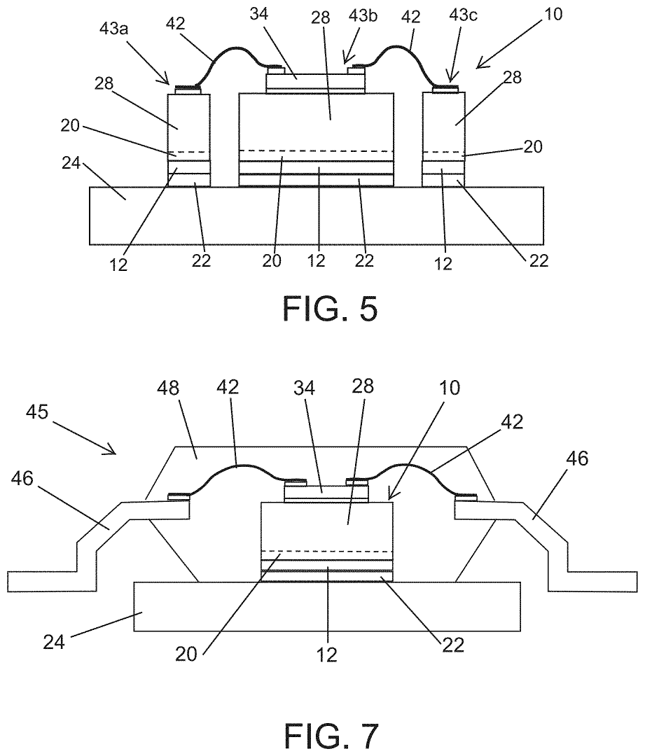

Another embodiment of the direct plated substrate 10 is depicted in FIG. 5. In the embodiment depicted in FIG. 5, the dielectric layer 12 is only provided in regions where electrical isolation is need, such as where a semiconductor component 34 is mounted or where electrical connections are made. In conventional DBC designs, the copper foil that bonds to the base plate and the dielectric layer are continuous layers, and the copper foil joined to the dielectric layer is substantially continuous except for regions of removal to provide electrical isolation. The large areas of copper foil on top of the continuous dielectric layer and continuous lower copper foil are necessitated by the need to balance stresses on the dielectric layer as a result of the high temperature and pressure during the direct copper bonding process. As shown in FIG. 5, however, the dielectric layer 12, the first metal layer 20, the second metal layer 22, and metal substrate 28 are provided only in regions 43a, 43b, 43c where a semiconductor component 34 is mounted or where electrical connections (e.g., shown by wire 42) are made. The direct plated substrate 10 is able to be formed in this way because of the difference in manufacturing method. That is, by first applying the metal layers 20, 22 to the thin, ribbon dielectric layer 12, the metal substrate 28 can be joined to first metal layer 20 in a manner that does not require the same high temperature and pressure as direct bonding copper. During assembly, the direct plated substrate 10 can be diced into segments, the segments can be positioned on a base plate 24, and then the metal substrate 28 can be attached to the first metal layer 20 of each segment. Such an assembly can be made similar to currently practiced component assembly operations. Conventional DBC could not be assembled in this way because of manner of joining the copper foils to the surfaces of the dielectric layer and the need to have the copper foils be continuous or substantially continuous on opposing surfaces of the dielectric layer to balance stresses during the high temperature and pressure forming operation.

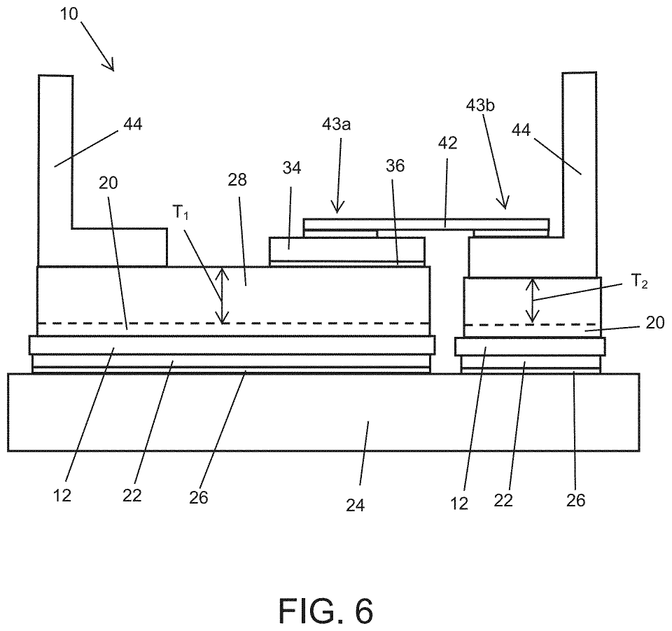

FIG. 6 depicts an embodiment of the direct plated substrate 10 in which the metal substrate 28 has different thicknesses in different regions 43a, 43b. As can be seen in FIG. 6, the direct plated substrate 10 has a first region 43a and a second region 43b. A semiconductor component 34 is mounted to the first region 43a. The first region 43a and the second region 43b each have terminals 44 for connecting the direct plated substrate 10 to external circuits, and the regions 43a, 43b are connected by a wire 42. The metal substrate 28 in the first region 43a has a first thickness T₁, and the metal substrate 28 in the second region 43b has a second thickness T₂. In embodiments, T₁ does not equal T₂. In embodiments, T₁ is greater than T₂, and in other embodiments, T₂ is greater than T₁. Advantageously, by varying the thicknesses T₁ and T₂ of the metal substrates 28, the inductances in the circuit formed on the direct plated substrate 10 can be minimized. Here, again, the manner of manufacturing the direct plated substrate 10 provides the ability to vary the thickness of the metal substrate 28 in different regions 43a, 43b, which is not available for conventional DBC. Further, while the variance in thickness of the metal substrate 28 is depicted with respect to the embodiment with a discontinuous dielectric layer 12, the thickness of the metal substrate 28 can be varied also in the embodiments shown in FIGS. 1-4, above, and in FIG. 7, discussed below.

FIG. 7 depicts another embodiment of the direct plated substrate 10 incorporated into a lead frame 45. As can be seen in FIG. 7, a semiconductor component 34 is mounted to the direct plated substrate 10. Wires 42 connect the semiconductor component 34 to leads 46 of the lead frame 45. The direct plated substrate 10, semiconductor component 34, wires 42, and portions of the leads 46 are contained in a mold compound 48, which protects the connections made by the wires 42. In general, lead frames are used for power modules having low to mid-level power. However, the lead frame 45 incorporating the direct plated substrate 10 of the present disclosure has improved thermal performance (particularly low thermal resistance) such that the lead frame 45 can be used for high power packaging.

A three-dimensional thermal model was developed to investigate the performance and effectiveness of the disclosed direct plated substrate 10 for removal of heat in an IGBT packaging unit. Power and electric modules, such as an IGBT packaging unit, often operate at high voltage and current which causes them to generate a large amount of heat, which causes the modules to become hot. For proper operation, the modules need to be maintained below predefined operating temperatures to avoid performance degradation or failure. However, the effort to miniaturize these modules while also increasing performance can create issues with effective thermal management because higher power demands result in greater heat generation while increased module density (as a result of miniaturization) reduces the size of cooling surfaces. The simulations were developed to investigate the power and thermal performance of the smaller designs according to the present disclosure in view of these various operating objectives.

In the simulations, different constructions of the substrate 10 as well as of different dielectric layer 12 materials and thicknesses were used and are summarized in Table 1, below. An energy equation, primarily accounting for the conduction mode of heat transport, was solved to evaluate temperature field across different components of a packaging unit. The maximum temperature (junction temperature) on the uppermost surface of the IGBT module, predicted from the model, was employed to evaluate the performance of each of the direct plated substrates in the packaging unit. For the embodiments according to the present disclosure, the schematic of the geometry used in the analysis is shown in FIG. 1. For the embodiments according to conventional designs, a similar layered construction was used but thicknesses were adjusted to reflect conventional limitations pertaining to dielectric layer selection and to processing conditions.

TABLE 1
Component Layers used for Thermal Analysis of IGBT Packaging Unit

| | | Thicknesses | | | | | | | |
|---|---|---|---|---|---|---|---|---|---|
| Layer | Material | CE1 | | CE2 | | E1 | | E2 | |
| Semiconductor | IGBT | 0.4 | mm | 0.4 | mm | 0.4 | mm | 0.4 | mm |
| component | | | | | | | | | |
| Solder Layer | Au—Sn | 20 | μm | 20 | μm | 20 | μm | 20 | μm |
| Metal | Cu | 250 | μm | 250 | μm | 275 | μm | 275 | μm |
| Substrate/First | | | | | | | | | |
| Metal Layer | | | | | | | | | |
| Dielectric Layer | CE1: AlN | 380 | μm | 250 | μm | 80 | μm | 40 | μm |
| | CE2: Al₂O₃ | | | | | | | | |
| | E1: Ribbon Al₂O₃ | | | | | | | | |
| | E2: Ribbon Al₂O₃ | | | | | | | | |
| Second Metal Layer | Cu | 250 | μm | 250 | μm | 25 | μm | 25 | μm |
| Solder Layer | Sintered Au | 10 | μm | 10 | μm | 10 | μm | 10 | μm |
| Base Plate | Cu | 3 | mm | 3 | mm | 3 | mm | 3 | mm |

As can be seen from Table 1, the second metal layer and dielectric layer for the comparative examples (CE1 and CE2) is larger than for the examples according to the present disclosure (E1 and E2). However, CE1 and CE2 do not contain a separate metal substrate and instead only have the first metal layer, which is the same thickness as the second metal layer. E1 and E2 have both the metal substrate and first metal layer, which is reflected in the larger combined thickness. Further, as can be seen in Table 1, the material or thickness of the dielectric layer is different between CE1, CE2, E1, and E2. Otherwise, the remaining components are all the same size and material.

The reason for the increased size of CE1 and CE2 relates to the conventional manufacturing process for forming direct bonded copper (DBC) in which copper foils are oxidized and heated in a sandwich structure around a dielectric layer to a temperature in excess of 1000° C. under pressure, which causes the copper oxide to bond to the ceramic. Because of the pressures involved, the dielectric layer needs to be thick, e.g., over 250 μm for alumina and generally aluminum nitride is only commercially available in thickness of over 600 The thickness of the copper foils is selected based on the current carried in the first metal layer. However, the copper foils must be the same size on both sides of the dielectric layer because any mismatch in the coefficient of thermal expansion may lead to warpage on account of mismatching stresses between the foils. Thus, in general, a conventional DBC with an alumina dielectric layer has a minimum thickness of 650 μm on account of the processing limitations. An aluminum nitride based DBC has a higher minimum thickness of about 780 μm.

E1 and E2 are manufactured in according to a different process as described above and utilize ceramic ribbon as the dielectric layer. Such ceramic ribbons are available in sizes of 100 μm and less. Further, because the direct plated substrates 10 according to the present disclosure are manufactured by plating metal layers 20, 22 onto the dielectric layer 12 and then bonding, soldering, or sintering the metal substrate 28 to the first metal layer 20, high temperatures and pressures are avoided that might cause warping, which allows for use of a thinner dielectric layer 12 and second metal layer 22 than in conventional designs.

Two sets of simulations were performed. In the first set, the power source at the top face of IGBT was maintained at 1.2 kW, and the bottom surface of the base plate was held at 25° C. The maximum temperature at the uppermost face of the IGBT module was evaluated for CE1, CE2, E1, and E2. In the second set, the maximum temperature at the junction face was kept constant at 150° C., and the corresponding power allowed each of CE1, CE2, E1, and E2 was computed. In the study, it was assumed that heat losses to surrounding air media were negligible and hence were ignored. Table 2, below, provides the thermal conductivities of the materials used in the thermal investigations for the various packaging unit designs.

TABLE 2
Thermal Conductivities of Materials used in Packaging Units

| Material | Thermal Conductivity (W/mK) |
|---|---|
| AlN | 180 |
| Al₂O₃ | 22 |
| Ribbon Al₂O₃ | 36 |
| Au—Sn | 57 |
| Cu | 385 |
| Sintered Au | 240 |

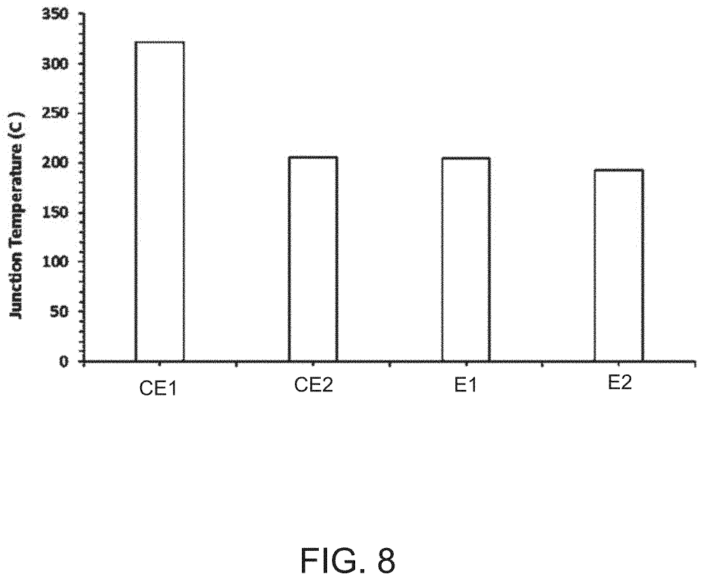

The results from the first set of simulations are depicted in a graph provided in FIG. 8. As can be seen there, CE2 had the highest by far junction temperature of over 300° C. As compared to CE1, E1 had a similar junction temperature of about 205° C. However, E1 utilizes ribbon Al₂O₃, which has a fifth of the thermal conductivity of the AlN used in CE1. Further, in terms of material cost, Al₂O₃ is much less expensive than AlN. Thus, E1 provides similar performance at lower cost and in a smaller package than CE1 (DBC components: 880 μm for CE1 vs. 380 μm for CE2). Further, E2 provided better performance with a junction temperature of about 192° C. using the less expensive Al₂O₃ and even smaller package (DBC components: 340 μm).

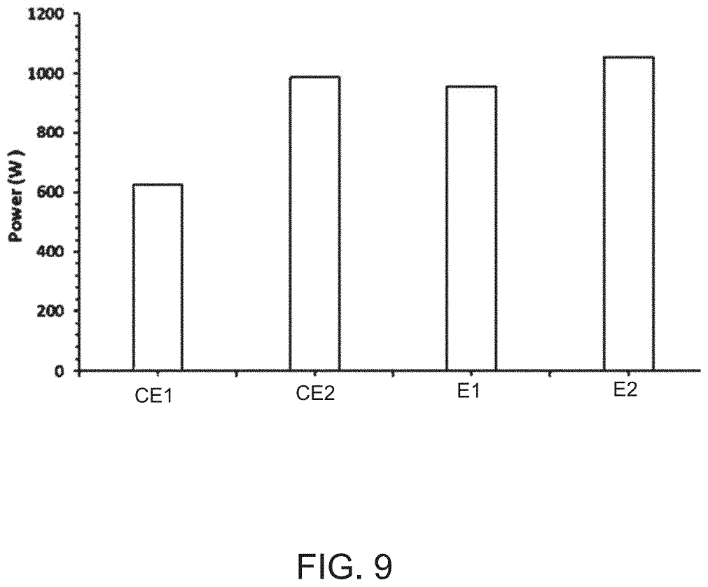

The results from the second set of simulations are depicted in a graph provided in FIG. 9. As can be seen there, CE2 again perform the worst with a power output of a little over 600 W. CE2 and E1 perform similarly with a power output of around 1000 W, and E2 performs the best with a power output of about 1050 W.

These simulations demonstrate that a direct plated substrate produced according to the present disclosure is able to provide lower thermal resistance to keep IC power modules from overheating and performing at their highest outputs for a given thermal condition. Additionally, the direct plated substrates according to the present disclosure provide an overall smaller size such more IC power modules may be incorporated in a given volume.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

What is claimed is:

1. Electronic packaging, comprising:
a dielectric layer comprising a first major surface, a second major surface opposite to the first major surface, and a thickness between the first major surface and the second major surface, the thickness being no more than 100 μm;
a first metal layer applied to the first major surface, the first metal layer having a thickness of from 2 μm to 50 μm;
a second metal layer applied to the second major surface, the second metal layer having a thickness of from 2 μm to 50 μm;
a metal substrate joined to the first metal layer; and
a base plate joined to the second metal layer.

2. The electronic packaging of claim 1, wherein the first metal layer is applied to the first major surface via electroplating or electroless plating and wherein the second metal layer is applied to the second major surface via electroplating or electroless plating.

3. The electronic packaging of claim 1, wherein the dielectric layer comprises at least one of alumina, zirconia toughened alumina, aluminum nitride, beryllium oxide, or silicon nitride.

4. The electronic packaging of claim 1, further comprising a sintered silver layer between the base plate and the second metal layer to join the base plate to the second metal layer.

5. The electronic packaging of claim 1, wherein the second metal layer and the base plate are a unitary layer after joining.

6. The electronic packaging of claim 1, wherein the first metal layer defines a first pattern of electrical connections and wherein the metal substrate defines a second pattern of electrical connections that matches the first pattern.

7. The electronic packaging of claim 1, wherein the metal substrate has a first thickness in a first region and a second thickness in a second region and wherein the first thickness is not equal to the second thickness.

8. Electronic packaging, comprising:
a dielectric layer comprising a first major surface, a second major surface opposite to the first major surface, and a thickness between the first major surface and the second major surface, the thickness being no more than 100 μm;
a first metal layer joined to the first major surface;
a second metal layer joined to the second major surface;
a metal substrate comprising a first substrate surface and a second substrate surface, the second substrate surface being joined to the first metal layer;
a base plate joined to the second metal layer; and
a semiconductor component joined to the first substrate surface of the metal substrate.

9. The electronic packaging of claim 8, wherein the dielectric layer comprises at least one of alumina, zirconia toughened alumina, aluminum nitride, or beryllium oxide.

10. The electronic packaging of claim 9, wherein the first metal layer defines a first pattern of electrical connections and wherein the metal substrate defines a second pattern of electrical connections that matches the first pattern.

11. The electronic packaging of claim 10, wherein the metal substrate has a first thickness in a first region upon which the semiconductor component is joined and a second thickness in a second region, wherein a gap separates the first region from the second region, and wherein the first thickness is not equal to the second thickness.

12. Electronic packaging, comprising:
a direct plated substrate, comprising:
a dielectric layer comprising a first major surface, a second major surface opposite to the first major surface, and a thickness between the first major surface and the second major surface, the thickness being no more than 100 μm;
a first metal layer joined to the first major surface;
a second metal layer joined to the second major surface;
a metal substrate comprising a first substrate surface and a second substrate surface, the second substrate surface being joined to the first metal layer;
a base plate joined to the second metal layer;
a semiconductor component joined to the first substrate surface of the metal substrate of the direct plated substrate; and
at least one lead configured to provide electrical communication with the semiconductor component.

13. The electronic packaging of claim 12, wherein each of the at least one lead is connected to the semiconductor component with a wire.

14. The electronic packaging of claim 13, wherein the dielectric layer, the first metal layer, the second metal layer, the metal substrate, the semiconductor component, the wire, and a portion of each of the at least one lead are encased in a mold compound.

15. The electronic packaging of claim 14, wherein the dielectric layer comprises at least one of alumina, zirconia toughened alumina, aluminum nitride, or beryllium oxide.

16. The electronic packaging of claim 15, wherein the first metal layer defines a first pattern of electrical connections and wherein the metal substrate defines a second pattern of electrical connections that matches the first pattern.

17. The electronic packaging of claim 16, wherein the semiconductor component comprises at least one integrated circuit power module.

18. The electronic packaging of claim 16, wherein the at least one integrated circuit power module comprises at least one of an insulated-gate bipolar transistor or a metal-oxide-semiconductor field-effect transistor.
